(19) United States
(12) Patent Application Publication
(10) Pub. No.: US 2024/0019484 A1
(43) Pub. Date: Jan. 18, 2024

(54) Automatic Selection of Connecting Cables for In-line Test

(71) Applicant: SOFTIRON LIMITED, CHILWORTH (GB)

(72) Inventors: Kevin Peters, Berlin (DE); Roman Laabs, Berlin (DE); Jason Van der Schyff, Newark, CA (US); Stephen Hardwick, Austin, TX (US)

(73) Assignee: SOFTIRON LIMITED, CHILWORTH (GB)

(21) Appl. No.: 18/347,268

(22) Filed: Jul. 5, 2023

Related U.S. Application Data
(60) Provisional application No. 63/358,355, filed on Jul. 5, 2022.

(51) Int. Cl. G01R 31/28

(52) U.S. Cl. CPC G01R 31/2844; G01R 31/2834

(57) ABSTRACT

An apparatus includes an interface to a device-under-test (DUT), an interface to a rack of cable holders, and a control circuit. Each cable holder is configured to raise or lower respective cable. The control circuit is configured to determine an internal configuration of the DUT and, based upon an internal configuration of the DUT, identify a plurality of cables to be used in testing the DUT. The control circuit is configured to cause the rack of cable holders to actuate a plurality of the cable holders associated with the identified plurality of cables to raise or lower the cable holders associated with the identified plurality of cables.

### PRIORITY

The present application claims priority to U.S. Provisional Patent Application No. 63/358,335 filed Jul. 5, 2022, the contents of which are hereby incorporated in their entirety.

### FIELD OF THE INVENTION

The present application relates to testing of manufactured devices and, more particularly, to providing automatic selection of connecting cables for an in-line test of manufactured devices.

### BACKGROUND

Often, burn-in and system testing of electronic devices is performed in batches using racks, rather than being performed in-line with an assembly conveyor during production. Inventors of embodiments of the present disclosure have discovered that performing this testing in-line within the manufacturing assembly line may eliminate the need to move a testing server off from a conveyor into additional testing areas. These other testing areas may be referred to as burn-in. Testing in-line may allow the tested units to move directly from a manufacturing conveyor into shipping. In some cases, the device under test, or DUT, may need to use manual connections of external cabling. Inventors of embodiments of the present disclosure have discovered that eliminating the need to move the DUT to or from the manufacturing assembly line may reduce damage to the DUTs and reduce delivery time.

Assembly lines may be used to produce different product configurations. The same or similar lines may be used to test products that have been returned for refurbishment and testing. In testing for refurbishment, the configuration of connecting cables may vary from DUT to DUT. Further, manual and even semi-automated selection of connecting cables may be fraught with error. For example, inventors of embodiments of the present disclosure have discovered that bar codes may be misread and incorrect cables may be selected. Such errors may result in damage, or destruction, of the DUT. Embodiments of the present disclosure may address one or more of these challenges.

### BRIEF DESCRIPTION OF THE DRAWINGS

FIG. 1A is an illustration of a system with a DUT in discovery position, according to examples of the present disclosure.

FIG. 1B is an illustration of a system with a DUT in test position, according to examples of the present disclosure.

FIG. 2 is an illustration of a cable feed with a hoist, according to examples of the present disclosure.

FIG. 3 is an illustration of a conveyor assembly, according to examples of the present disclosure.

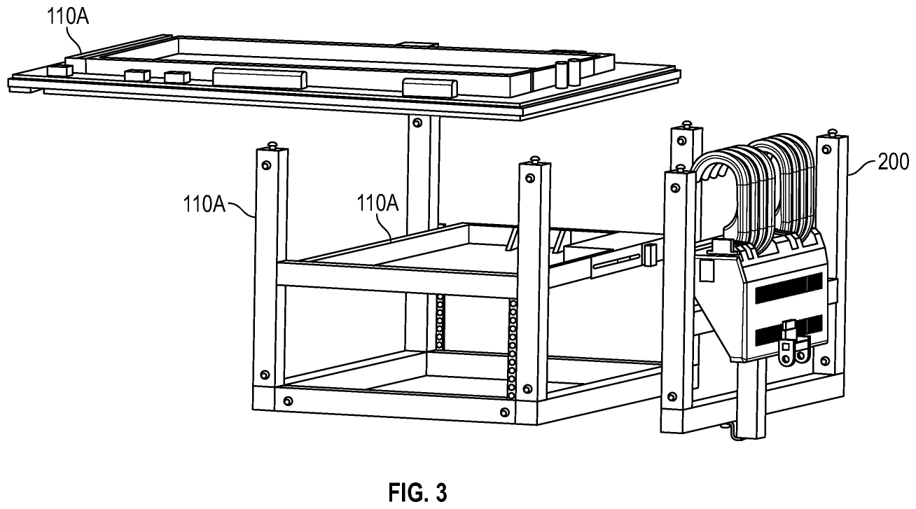

### DETAILED DESCRIPTION

Embodiments of the present disclosure may address one or more challenges of selecting correct cables for DUT testing. Such selection may occur in an in-line test system.

A first challenge addressed by embodiments of the present disclosure to test a DUT may be to determine the exact configuration of the DUT. This may include identifying a make, model, or other instance of the DUT. More particularly, this may include identifying internal configurations of the DUT, such as how many storage devices are located therein, the identity of the storage devices, etc. Such internal configurations might not be evident from the make, model, serial number, or other identifiers of the DUT, or from the external appearance of the DUT. In other solutions, the DUT might have to be powered up in order for the DUT to be polled for its contents and for the DUT to be provided for testing. However, to power up the DUT might require cabling, and selection of which cables to sufficiently power up the DUT might not be known or may be imprecise. In one embodiment, the determination of the exact internal configuration of the DUT may be performed by powering-on certain parts of the DUT, such as a controller, but without providing power or before providing power to main components of the DUT such as a motherboard or main processor. Moreover, providing power to main components of the DUT may interfere with system testing. Plugging in the power cords themselves may cause testing problems if an incorrect power cord is selected, wherein the incorrect power cord causes interference or damage or incorrect voltages to be used, or if a power cord interface is partially damaged. Once the configuration of the DUT has been determined, the correct set of connecting cables may be provided to a test system to apply to the DUT. However, a second challenge may be that using external indicators, such as bar codes, may not truly reflect the DUT configuration, especially with returned items. A third challenge may exist in that, as the cables are connected to the DUT, slack in the cables may be removed to ensure a functional connection. Powering the DUT through out of band channels, such as with a baseboard management controller or wirelessly, may allow query of the DUT contents sufficient for configuration information.

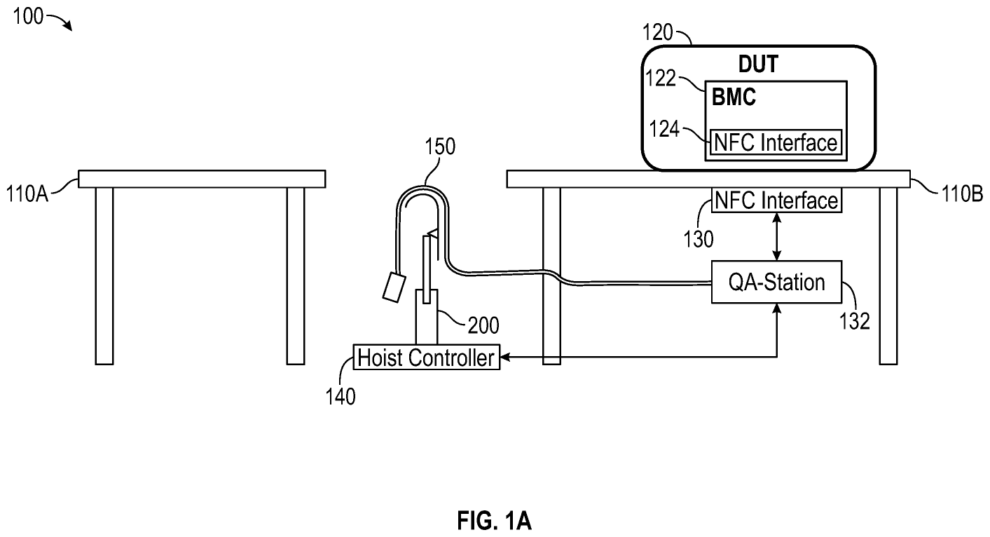

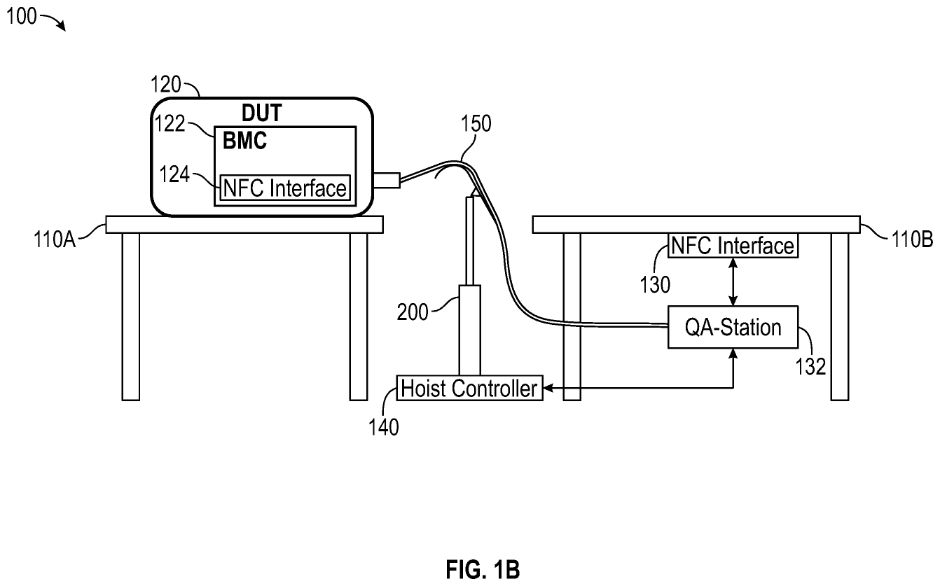

FIGS. 1A-1B are an illustration of a system 100 with a DUT 120, according to embodiments of the present disclosure. FIG. 1A illustrates DUT 120 in a discovery position, while FIG. 1B illustrates DUT 120 in a test position.

In system 100, DUT 120 may be placed on a production conveyor 110. Production conveyer 110 may be implemented in stand-alone fashion or as part of a larger manufacturing conveyor system (not shown). Production conveyer 110 may include any suitable mechanism for conveying DUT 120 from, in the present example, left to right or from right to left as shown in FIG. 1. Production conveyer 110 may be split into two parts 110A and 110B. A gap or space may exist between parts 110A, 110B. DUT 120 may be on conveyor portion 110B (as shown in FIG. 1A) or on conveyor portion 110A (as shown in FIG. 1B). The space between production conveyors 110A and 110B may allow for any suitable number and kind of cables 150 to be provided to be attached to DUT 120 after DUT 120 has moved position from right to left between 110B and 110A between FIGS. 1A and 1B. The tester operating system 100 may be a technician or a robot, for example, and may be responsible for connecting cables 150 to DUT 120.

DUT 120 may be implemented in any suitable manner, such as any suitable electronic device that may undergo testing or validation. DUT 120 may include various baseline functionality and implementations, not discussed here. Moreover, DUT 120 may include a baseboard management controller (BMC). BMC 122 may be implemented in any suitable manner, such as by analog circuitry, digital circuitry, control logic, instructions for execution by a processor, digital logic circuits programmed through hardware description language, application specific integrated circuits (ASIC), field programmable gate arrays (FPGA), programmable logic devices (PLD), or any suitable combination thereof, whether in a unitary device or spread over several devices. BMC 122 may be implemented, for example, by a board with a processor and memory and any suitable communication interfaces. BMC 122 may be configured to examine the configuration of DUT 120 without powering the rest of the component systems. BMC 122 may do so by providing minimal power to buses, peripherals, or drives without powering a motherboard or main processor. Moreover, BMC 122 may provide power in an out-of-band manner that only powers up the components that are to be queried. And out-of-band powering of components may include, for example, power over Ethernet or other any other suitable protocols in which power may be provided by BMC 122, rather than a main power supply of DUT 120, in which individual components or sub-systems are selectively powered while the rest of DUT 120 remains unpowered. In particular, as discussed, a motherboard or main processor might not be powered. Near Field Communications (NFC) interface 124 or other wireless protocols may allow external communications to or from BMC 122. Power can also be supplied wirelessly via NFC interface 124, such as by using the NFC wireless charging specification (WLC). The power required to operate BMC 122 may be sufficiently low that it can utilize the amount of power supplied by such an interface. BMC 122 may be configured to selectively power on various components of DUT in order to interrogate or query components for the relevant configuration therein. As discussed above, BMC 122 may do so in an out of band manner, without powering on main components of DUT such as a motherboard processor, main power supply, modules, front panel, or motherboard subassemblies.

Conveyer portion 110B may include an NFC interface 130. This may supply power and NFC connectivity to BMC 122 via NFC interface 124. Any other suitable wireless protocol may be used. When power is supplied through NFC interface 130 to NFC interface 124, this may activate BMC 122. NFC interface 130 may be connected to quality assurance (QA) station 132. QA station 132 may be configured to issue commands to BMC 122 once BMC 122 has been activated using NFC connection 130. These commands may instruct BMC 122 to determine the configuration of DUT 120. DUT 120 configuration, once determined by BMC 122, may be sent via NFC interfaces 124, 130 to QA station 132. QA Station 132 may then determine which connection cables are to be used to test DUT 120.

QA station 132 may be implemented in any suitable manner, such as by analog circuitry, digital circuitry, control logic, instructions for execution by a processor, digital logic circuits programmed through hardware description language, ASIC, FPGA, PLD, or any suitable combination thereof, whether in a unitary device or spread over several devices. QA station 132 may be implemented by, for example, a server, computer, or any other suitable electronic device. QA station 132 may include any suitable interfaces to access BMC 122 to determine the configuration of DUT 120. QA station 132 may include any suitable interfaces to power BMC 122 to determine the configuration of DUT 120.

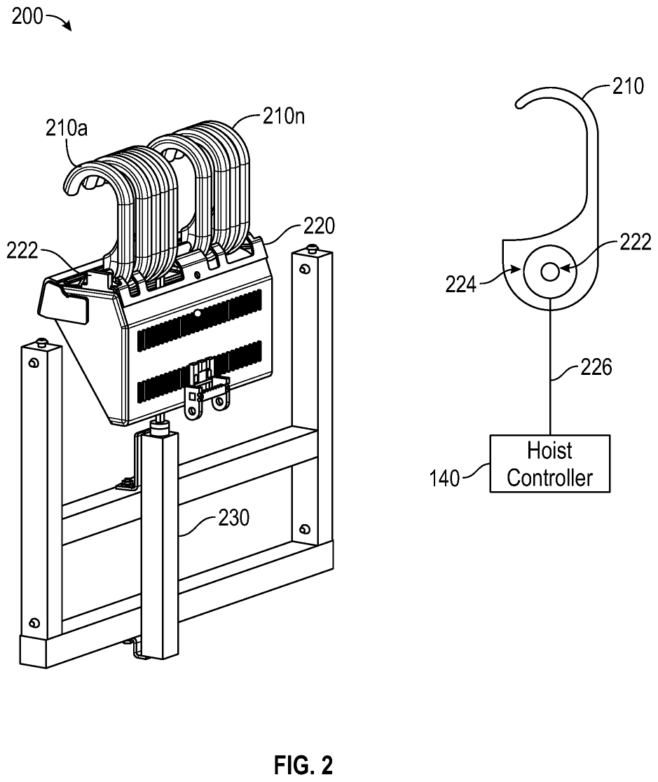

Rails, wheels, or any other suitable mechanical component, not shown, may be used to move DUT 120 from conveyor portion 110B to 110A. The rails may connect both conveyor sections 110. This may allow DUT 120 to pass over the gap between portions 110 and pass over connecting cable 150 and cable hoist assembly 200. This may result in DUT 120 being positioned on conveyor portion 110A as shown in FIG. 2. Moreover, in some instances, DUT 120 may be of a length sufficiently long so as to bridge the gap between conveyor portions 110 while sliding between conveyor portions 110.

In FIG. 1A, when DUT 120 is positioned on conveyor portion 110B, cables 150 may be below conveyor 110. This may allow DUT 120 to pass from conveyor portion 110B to 110A without any interference from cables 150. When DUT 120 is in position on conveyor portion 110A in FIGURE AB, a subset of cables 150 may be selectively raised by cable hoist 200. The operator of system 100 can then manually connect cables 150 to DUT 120 as shown in FIG. 1B. QA station 132 may be connected to hoist controller 140. QA station 132 may issue a command to hoist controller 140 to selectively raise some of cables 150 after DUT 120 has moved to conveyor portion 110A, based upon the determined configuration of DUT 120. The ones of cables 150 that are selectively raised may be determined by QA station 132 and may be based upon the determined configuration of DUT 120. The ones of cables 150 that are selectively raised may be a minimum set of cables 150 needed to be connected to DUT 120 to validate or test DUT 120.

In other embodiments, QA station 132 may cause selectively raising of some of cables 150 for manual connection to DUT 120 at any suitable time or for any suitable position of DUT 120. For example, in other embodiments (not shown), QA station 132 may cause raising of cables 150 for DUT 120 when DUT 120 is in any suitable position, such as on conveyer portion 110B. In such cases, cable hoist 200 may be located in any suitable place, position, or orientation.

FIG. 2 is an illustration of cable feed with a cable hoist 200, according to examples of the present disclosure.

Cable hoist 200 may include any suitable number of cable holders 210, a cable holder actuator 220, and hoist 230.

Cable holders 210 may be implemented in any way to support cables 150 and to allow cables to move through cable holders. For example, cables 150 may be strung through a groove on top of cable holders 210. The groove may be open or closed to the top of cable holders 210. A given one of cable holders 210 can be in a vertical, or more vertical than horizontal, position to raise a cable 150 strung therethrough sufficient for a tester to access the cable 150 to attach to DUT 120, when selected by QA station 132. A given one of cable holders 210 can be in a horizontal position (not shown) (or less than vertical position compared to unselected cable holders 210), achieved by, for example, rotating anti-clockwise by 90 degrees to lower a cable 150 strung therethrough. The rotation of each cable holder 210 may be controlled by hoist controller 140 and cable holder actuator 220. Moreover, actuator 220 may be implemented by formed plastic components on a spring loaded pivot, and may be configured to raise or lower a given cable 150 by rotating the associated holder 210 between the vertical and horizontal positions. Again, the vertical and horizontal positions need not be at 180°/270° for a horizontal position or at 90° for a vertical position, but may be more vertical when selected relative to unselected, and more horizontal when selected relative to unselected. Nevertheless, in shorthand in this disclosure the positions may be referred to as vertical and horizontal.

Each cable holder 210 can hold an individual cable, or a bundled or group of cables. Any suitable number of cable holders 210 may be included so that any suitable number and combination of cables 150 can be selected and hoisted or lowered for use with a given DUT 120 based upon the configuration of DUT 120. Each cable holder 210 capable of holding a cable or group of cables may facilitate direct connections between QA station 132 and DUT 120. Hoist controller 140 may be configured to select which of cables 150 are to be presented to the tester. If a cable 150 is to be selected and used for a given DUT 120, then the associated cable holder 210 may be in the vertical position. If a cable 150 is not to be selected and used for a given DUT 120, then the associated cable holder 210 may be in the horizontal position. As a result of being in the horizonal position, the associated cable holder 210 may result in cable 150 hanging below conveyor 110A.

Movement between vertical and horizontal positions may be enabled in any suitable manner. For example, cable holder 210 may include a spring-loaded pivot as part of cable holder actuator 220. This pivot may enable the movement of cable holder 210 to be moved between the vertical and the horizontal positions. Contained within each cable holder 210 may be a high precision direct drive integrated servo motor 224. A single rod 222 may run from one side of cable holder actuator 220 to the other connecting each cable holder 210. Part of servo motor 224 on each cable holder 210 may be physically attached directly to rod 222. The second rotational element of servo motor 224 may be directly physically attached to cable holder 210 in conjunction with a spring-loaded pivot. This may allow servo motor 224 to rotate cable holder 210 around rod 222 in a controlled fashion. Each servo motor 22 may be electrically connected, via cable 226, to hoist controller 140. QA station 132, by signaling hoist controller 140 and cable 226, may control the position of cable holder 210 by signaling servo motor 224. Cable holder 210 may be in a horizontal, vertical, or other rotational angular position independent of the position of cable hoist 200. This may result in, for example, individual cable holders being dynamically positioned by QA station 132, effectively reconfiguring the available cable set 150 presented to users of system 100 as DUT 120 tests progress.

Moreover, when a specific cable 150 is connected to DUT 120 by the tester, cable holder 210 may further rotate as necessary as cable 150 is moved toward DUT 120. This may cause the spring pivot in cable holder actuator 220 to relieve physical stress or tension on cable 150. The spring-loaded pivot of cable holder 210 may allow such physical rotation in response to the physical stress or tension.

As discussed above, QA station 132 can use BMC 122, via NFC interfaces 124, 130, or any other suitable protocol, to obtain an accurate configuration of DUT 120 from querying portions of DUT 120. Using this configuration, QA station 132 can determine which instances of cables 150 that are to be used for testing DUT 150. This configuration information can be contained in any suitable way, such as in QA station 132 via BMC 112 to access DUT 120 without fully powering on DUT 120, as discussed above. Once determined, QA station 132 may provide configuration data or instructions to hoist controller 140. If a particular cable 150 is needed to be moved to a vertical position based upon the configuration data, then the respective cable holder 210 for the particular cable may be put into a vertical position. Others not required may be placed in a horizontal position. The tester need only connect those cables 150 for which cable holders 210 are in a vertical position.

The following tables shows example positions of various cable holders 210 after hoist 230 has raised cable holder actuator 220, and then actuator 220 in turn has raised various cable holders 210 and cables 150 therethrough according to the configuration of the given DUT 120. Prior to moving to conveyor portion 110A, QA station 132 may have queried DUT 120 using BMC 122 via NCF interfaces 124, 130 to determine such a configuration of DUT 120. The tables show the configuration of cable holders 210 for three different DUT configurations. In each configuration, and not shown in the tables, various power cables (210-1 and 210-2), Ethernet cables (210-3), and USB cables (210-4) may be used to connect externally to a BMC of DUT 120, and Ethernet (210-5) and USB (210-6) cables may be used to connect to a server component of DUT 120 for out of band management, such as IPMI. The contents of each table illustrate additional cables that may be raised for the given configuration. Here are three sample configurations, and a fourth summary table.

TABLE 1
Example DUT Configuration 1 (8 storage media devices)

| Cables | Cable type | Function |
|---|---|---|
| 210-9 | SFP28 25 GbE Twinaxial Direct | Storage Network Port |
| | Attach Cable | |
| 210-12 | SFP28 25 GbE Twinaxial Direct | Storage Network Port |
| | Attach Cable | |

Table 1 shows that a given DUT 120 of a configuration 1 may include 8 storage media devices, and may particularly additionally use two cables 150, each a SFP28 25 GbE Twinaxial Direct Attach Cable. These cables 150 may be housed in respective holders 210-9 and 210-12, which may be raised in the vertical position when DUT 120 with configuration 1 is in a position for testing, such as after a transfer from portion 110B to portion 110A.

TABLE 2
DUT Configuration 2 (8 network interface devices)

| Cables | Cable type | Function |
|---|---|---|
| 210-9 | SFP28 25 GbE Twinaxial Direct | Router Network Port |
| | Attach Cable | |
| 210-12 | SFP28 25 GbE Twinaxial Direct | Router Network Port |
| | Attach Cable | |
| 210-15 | SFP28 25 GbE Twinaxial Direct | Router Network Port |
| | Attach Cable | |
| 210-18 | SFP28 25 GbE Twinaxial Direct | Router Network Port |
| | Attach Cable | |
| 210-21 | SFP28 25 GbE Twinaxial Direct | Router Network Port |
| | Attach Cable | |
| 210-24 | SFP28 25 GbE Twinaxial Direct | Router Network Port |
| | Attach Cable | |
| 210-27 | SFP28 25 GbE Twinaxial Direct | Router Network Port |
| | Attach Cable | |
| 210-30 | SFP28 25 GbE Twinaxial Direct | Router Network Port |
| | Attach Cable | |

Table 2 shows that a given DUT 120 of a configuration 2 may include 8 network interface devices, and may particularly and additionally use eight cables 150, each a SFP28 25 GbE Twinaxial Direct Attach Cable. These cable 150 may be housed in respective holders 210-9, 210-12, 210-15, 210-18, 210-21, 210-24, 210-27, 210-30, which may be raised in the vertical position when DUT 120 with configuration 2 is in a position for testing, such as transfer from portion 110B to portion 110A.

TABLE 3
DUT Configuration 3 (8 USB interface devices)

| Cables | Cable type | Function |
|---|---|---|
| 210-8 | USB Cable | USB Port |
| 210-11 | USB Cable | USB Port |
| 210-14 | USB Cable | USB Port |
| 210-17 | USB Cable | USB Port |
| 210-20 | USB Cable | USB Port |
| 210-23 | USB Cable | USB Port |
| 210-26 | USB Cable | USB Port |
| 210-29 | USB Cable | USB Port |

Table 3 shows that a given DUT 120 of a configuration 2 may include 8 USB devices, and may particularly and additionally use eight cables 150, each a USB cable. These cables 150 may be housed in respective holders 210-8, 210-11, 210-14, 210-17, 210-20, 210-23, 210-26, 210-29, which may be raised in the vertical position when DUT 120 with configuration 3 is in a position for testing, such as transfer from portion 110B to portion 110A.

TABLE 4

| | | DUT | DUT | DUT |
|---|---|---|---|---|
| Cable | | Configuration | Configuration | Configuration |
| Holder | Cable type | 1 | 2 | 3 |
| 210-1 | Power Cord | Vertical | Vertical | Vertical |
| 210-2 | Power Cord | Vertical | Vertical | Vertical |
| 210-3 | Ethernet RJ45 | Vertical | Vertical | Vertical |
| 210-4 | USB Cable | Vertical | Vertical | Vertical |
| 210-5 | Ethernet RJ45 | Vertical | Vertical | Vertical |
| 210-6 | USB Cable | Vertical | Vertical | Vertical |
| 210-7 | Ethernet RJ45 | Horizontal | Horizontal | Horizontal |
| 210-8 | USB Cable | Horizontal | Horizontal | Vertical |
| 210-9 | SFP28 25 GbE Twinaxial | Vertical | Vertical | Horizontal |
| | Direct Attach Cable | | | |
| 210-10 | Ethernet RJ45 | Horizontal | Horizontal | Horizontal |
| 210-11 | USB Cable | Horizontal | Horizontal | Vertical |
| 210-12 | SFP28 25 GbE Twinaxial | Vertical | Vertical | Horizontal |
| | Direct Attach Cable | | | |
| 210-13 | Ethernet RJ45 | Horizontal | Horizontal | Horizontal |
| 210-14 | USB Cable | Horizontal | Horizontal | Vertical |
| 210-15 | SFP28 25 GbE Twinaxial | Horizontal | Vertical | Horizontal |
| | Direct Attach Cable | | | |
| 210-16 | Ethernet RJ45 | Horizontal | Horizontal | Horizontal |
| 210-17 | USB Cable | Horizontal | Horizontal | Vertical |
| 210-18 | SFP28 25 GbE Twinaxial | Horizontal | Vertical | Horizontal |
| | Direct Attach Cable | | | |
| 210-19 | Ethernet RJ45 | Horizontal | Horizontal | Horizontal |
| 210-20 | USB Cable | Horizontal | Horizontal | Vertical |
| 210-21 | SFP28 25 GbE Twinaxial | Horizontal | Vertical | Horizontal |
| | Direct Attach Cable | | | |
| 210-22 | Ethernet RJ45 | Horizontal | Horizontal | Horizontal |
| 210-23 | USB Cable | Horizontal | Horizontal | Vertical |
| 210-24 | SFP28 25 GbE Twinaxial | Horizontal | Vertical | Horizontal |
| | Direct Attach Cable | | | |
| 210-25 | Ethernet RJ45 | Horizontal | Horizontal | Horizontal |
| 210-26 | USB Cable | Horizontal | Horizontal | Vertical |
| 210-27 | SFP28 25 GbE Twinaxial | Horizontal | Vertical | Horizontal |
| | Direct Attach Cable | | | |
| 210-28 | Ethernet RJ45 | Horizontal | Horizontal | Horizontal |
| 211-29 | USB Cable | Horizontal | Horizontal | Vertical |
| 212-30 | SFP28 25 GbE Twinaxial | Horizontal | Vertical | Horizontal |
| | Direct Attach Cable | | | |

Table 4 shows an overview of possible cables 150 that might be applied to a given DUT 120 with configurations 1, 2, or 3 by QA station 132. Each such cable 150 may be housed in a respective holder 210, shown above. Also shown are the three example configurations from Tables 1-3. Notably, and as discussed above, these configurations may also use a baseline or common set of cables 150, shown as those housed in holders 210-1, 210-2, 210-3, 210-4, 210-5, 210-6, which may also be raised in the vertical position when DUT 120 is in a position for testing, such as transfer from portion 110B to portion 110A. Moreover, as shown, some cables, such as cable 150 house in 210-9, might be used in multiple but not all DUT 120 configurations.

Embodiments of the present disclosure include an apparatus. The apparatus may include an interface to a DUT. The interface may be wired or wireless. The apparatus may include an interface to a rack of cable holders. In the rack of cable holders, each cable holder may be configured to raise or lower respective cable. The apparatus may include a control circuit. The control circuit may be implemented in any suitable manner, such as by analog circuitry, digital circuitry, control logic, instructions for execution by a processor, digital logic circuits programmed through hardware description language, ASIC, FPGA, PLD, or any suitable combination thereof, whether in a unitary device or spread over several devices. The control circuit may be configured to determine an internal configuration of the DUT. The control circuit may be configured to determine the internal configuration of the DUT by querying the DUT. The query may be made to a BMC of the DUT. The control circuit may be configured to, based upon an internal configuration of the DUT, identify a plurality of cables to be used in testing the DUT. The control circuit may be configured to, based upon the identification of the plurality of cables and the internal configuration of the DUT, cause the rack of cable holders to actuate a plurality of the cable holders associated with the identified plurality of cables to raise or lower the cable holders associated with the identified plurality of cables.

In combination with any of the above embodiments, the control circuit may be configured to determine the internal configuration of the DUT and the plurality of cables to be used in testing the DUT through a baseboard management controller (BMC) of the DUT.

In combination with any of the above embodiments, the control circuit may be configured to determine the internal configuration of the DUT and the plurality of cables to be used in testing the DUT through wirelessly powering the BMC of the DUT.

In combination with any of the above embodiments, the control circuit may be configured to determine the internal configuration of the DUT to identify and actuate the plurality of cables to be used in testing the DUT without fully powering the DUT.

In combination with any of the above embodiments, the control circuit may be configured to determine the internal configuration of the DUT to identify and actuate the plurality of cables to be used in testing the DUT while powering the DUT sufficiently to query internal components of the DUT without booting the DUT.

In combination with any of the above embodiments, the control circuit may be configured to determine the internal configuration of the DUT to identify and actuate the plurality of cables to be used in testing the DUT while powering the DUT sufficiently to query internal components of the DUT in an out-of-band channel with respect to a main processor of the DUT.

In combination with any of the above embodiments, the control circuit may be configured to cause the rack of cable holders to actuate the plurality of the cable holders after the DUT has been queried for the internal configuration of the DUT and after the DUT is in a position to be tested.

In combination with any of the above embodiments, the control circuit may be configured to cause the rack of cable holders to actuate the plurality of the cable holders after the DUT has moved over a gap in a conveyor line, the rack of cable holders located in the gap.

Embodiments of the present disclosure may include a rack of cable holders. The rack of cable holders may include any suitable number and kind of cable holders. The cable holders may be configured to each raise or lower a cable. The cable holders may be actuated through a hoist. The hoist and cable holders may be implemented in any suitable manner.

Embodiments of the present disclosure may include a test system. The test system may include any of the above apparatuses included in a QA station. The test system may include any of the above racks of cable holders. The test system may include a production conveyer. The test system may include any suitable number and kind of cables to be attached to a DUT in a test position.

Embodiments of the present disclosure may include a method of communicating with a DUT. The method may be performed using any of the above embodiments. The method may include connecting to the DUT, and connecting to a rack of cable holders, wherein each cable holder may be configured to raise or lower respective cable. The method may include determining an internal configuration of the DUT. The method may include, based upon an internal configuration of the DUT, identifying a plurality of cables to be used in testing the DUT. The method may include, based upon the identification of the plurality of cables and the internal configuration of the DUT, causing the rack of cable holders to actuate a plurality of the cable holders associated with the identified plurality of cables to raise or lower the cable holders associated with the identified plurality of cables.

In combination with any of the above embodiments, the method may include determining the internal configuration of the DUT and the plurality of cables to be used in testing the DUT through a BMC of the DUT.

In combination with any of the above embodiments, the method may include determining the internal configuration of the DUT and the plurality of cables to be used in testing the DUT through wirelessly powering the BMC of the DUT.

In combination with any of the above embodiments, the method may include determining the internal configuration of the DUT to identify and actuate the plurality of cables to be used in testing the DUT without fully powering the DUT.

In combination with any of the above embodiments, the method may include determining the internal configuration of the DUT to identify and actuate the plurality of cables to be used in testing the DUT while powering the DUT sufficiently to query internal components of the DUT without booting the DUT.

In combination with any of the above embodiments, the method may include determining the internal configuration of the DUT to identify and actuate the plurality of cables to be used in testing the DUT while powering the DUT sufficiently to query internal components of the DUT in an out-of-band channel with respect to a main processor of the DUT.

In combination with any of the above embodiments, the method may include causing the rack of cable holders to actuate the plurality of the cable holders after the DUT has been queried for the internal configuration of the DUT and after the DUT is in a position to be tested.

In combination with any of the above embodiments, the method may include causing the rack of cable holders to actuate the plurality of the cable holders after the DUT has moved over a gap in a conveyor line, the rack of cable holders located in the gap.

Embodiments of the present disclosure may include methods performed by any of the above embodiments, including the systems, apparatuses, or racks.

Embodiments of the present disclosure may include methods including performing tests upon the DUT using any of the above embodiments.

Although examples have been described above, other variations and examples may be made from this disclosure without departing from the spirit and scope of these examples.

We claim:

1. An apparatus, comprising:
an interface to a device-under-test (DUT);
an interface to a rack of cable holders, each cable holder configured to raise or lower respective cable; and
a control circuit configured to:
determine an internal configuration of the DUT;
based upon an internal configuration of the DUT, identify a plurality of cables to be used in testing the DUT; and
based upon the identification of the plurality of cables and the internal configuration of the DUT, cause the rack of cable holders to actuate a plurality of the cable holders associated with the identified plurality of cables to raise or lower the cable holders associated with the identified plurality of cables.

2. The apparatus of claim 1, wherein the control circuit is configured to determine the internal configuration of the DUT and the plurality of cables to be used in testing the DUT through a baseboard management controller (BMC) of the DUT.

3. The apparatus of claim 2, wherein the control circuit is configured to determine the internal configuration of the DUT and the plurality of cables to be used in testing the DUT through wirelessly powering the BMC of the DUT.

4. The apparatus of claim 1, wherein the control circuit is configured to determine the internal configuration of the DUT to identify and actuate the plurality of cables to be used in testing the DUT without fully powering the DUT.

5. The apparatus of claim 1, wherein the control circuit is configured to determine the internal configuration of the DUT to identify and actuate the plurality of cables to be used in testing the DUT while powering the DUT sufficiently to query internal components of the DUT without booting the DUT.

6. The apparatus of claim 1, wherein the control circuit is configured to determine the internal configuration of the DUT to identify and actuate the plurality of cables to be used in testing the DUT while powering the DUT sufficiently to query internal components of the DUT in an out-of-band channel with respect to a main processor of the DUT.

7. The apparatus of claim 1, wherein the control circuit is configured to cause the rack of cable holders to actuate the plurality of the cable holders after the DUT has been queried for the internal configuration of the DUT and after the DUT is in a position to be tested.

8. The apparatus of claim 7, wherein the control circuit is configured to cause the rack of cable holders to actuate the plurality of the cable holders after the DUT has moved over a gap in a conveyor line, the rack of cable holders located in the gap.

9. A method of communicating with a device-under-test (DUT), comprising:
connecting to the DUT;
connecting to a rack of cable holders, each cable holder configured to raise or lower respective cable;
determining an internal configuration of the DUT;
based upon an internal configuration of the DUT, identifying a plurality of cables to be used in testing the DUT; and
based upon the identification of the plurality of cables and the internal configuration of the DUT, causing the rack of cable holders to actuate a plurality of the cable holders associated with the identified plurality of cables to raise or lower the cable holders associated with the identified plurality of cables.

10. The method of claim 9, comprising determining the internal configuration of the DUT and the plurality of cables to be used in testing the DUT through a baseboard management controller (BMC) of the DUT.

11. The method of claim 10, comprising determining the internal configuration of the DUT and the plurality of cables to be used in testing the DUT through wirelessly powering the BMC of the DUT.

12. The method of claim 9, comprising determining the internal configuration of the DUT to identify and actuate the plurality of cables to be used in testing the DUT without fully powering the DUT.

13. The method of claim 9, comprising determining the internal configuration of the DUT to identify and actuate the plurality of cables to be used in testing the DUT while powering the DUT sufficiently to query internal components of the DUT without booting the DUT.

14. The method of claim 9, comprising determining the internal configuration of the DUT to identify and actuate the plurality of cables to be used in testing the DUT while powering the DUT sufficiently to query internal components of the DUT in an out-of-band channel with respect to a main processor of the DUT.

15. The method of claim 9, comprising causing the rack of cable holders to actuate the plurality of the cable holders after the DUT has been queried for the internal configuration of the DUT and after the DUT is in a position to be tested.

16. The method of claim 15, comprising causing the rack of cable holders to actuate the plurality of the cable holders after the DUT has moved over a gap in a conveyor line, the rack of cable holders located in the gap.
